(19) United States
(12) Patent Application Publication
(10) Pub. No.: US 2025/0236562 A1
(43) Pub. Date: Jul. 24, 2025

(54) GREEN SHEET, METHOD FOR MANUFACTURING SILICON NITRIDE SINTERED BODY, AND SILICON NITRIDE SINTERED BODY

(71) Applicant: TOKUYAMA CORPORATION, Shunan-shi, Yamaguchi (JP)

(72) Inventors: Dai KUSANO, Sendai-shi (JP); Kunihiro GOTOH, Shunan-shi (JP)

(73) Assignee: TOKUYAMA CORPORATION, Shunan-shi, Yamaguchi (JP)

(21) Appl. No.: 18/705,397

(22) PCT Filed: Dec. 14, 2022
(86) PCT No.: PCT/JP2022/046067

§ 371 Date: Apr. 26, 2024

(30) Foreign Application Priority Data
Dec. 23, 2021 (JP) 2021-209994

(51) Int. Cl. C04B 35/587; C04B 35/634; C04B 35/638

(52) U.S. Cl. CPC C04B 35/587; C04B 35/63424; C04B 35/638; C04B 2235/3873

(57) ABSTRACT

Provided is a green sheet, comprising a raw material powder and a binder resin, in which the raw material powder contains a silicon nitride powder, and a glass transition temperature of the binder resin is less than −20° C.

### TECHNICAL FIELD

The present invention relates to a green sheet, a method for producing a silicon nitride sintered body, and a silicon nitride sintered body.

### BACKGROUND ART

Ceramic sintered bodies obtained by sintering ceramic powders such as silicon nitride, aluminum nitride, and boron nitride generally have excellent properties such as high thermal conductivity, high insulating properties, and high strength. Therefore, such ceramic sintered bodies are attracting attention as various industrial materials.

For example, a silicon nitride sintered body is used in ecologically friendly vehicles such as an electric vehicle, a hydrogen-fueled vehicle, and a hybrid vehicle, and as insulating substrates for power semiconductor devices in the field of renewable energies such as solar power generation and wind power generation.

Silicon nitride is known as a ceramic material excellent in oxidation resistance, corrosion resistance, and thermal conductivity. The sintered body thereof has high mechanical strength and is used in many industrial fields as described above.

Examples of a method for obtaining a ceramic sintered body include a method in which a ceramic powder is granulated into granules, then molded by dry pressing to obtain a press molded body, which is then fired, and a method in which a ceramic powder is wet molded to obtain a green sheet, which is degreased and then fired. For the production of the green sheet of the latter, a method is generally adopted in which a ceramic powder, a binder resin, a plasticizer, a sintering aid, an organic solvent, and the like are mixed with a ball mill or the like and a sheet is molded by a doctor blade method or the like. After the sheet molding, a ceramic sintered body is obtained through a degreasing step of decomposing and removing the binder resin by heating, and a firing step of sintering the ceramic powder (Patent Document 1).

### CITATION LIST

### Patent Literature

Patent Document 1: WO2021/095843

### SUMMARY OF INVENTION

### Technical Problem

As described above, a green sheet including a ceramic powder, a binder resin, a plasticizer, and a sintering aid is fired after a degreasing step of removing organic substances such as a binder resin.

There is a problem that the higher the content of organic substances such as a binder resin and a plasticizer in the green sheet is, the longer the time required for a degreasing treatment is, which decreases productivity. Further, another problem arises that when the amount of organic substances such as a binder resin and a plasticizer in the green sheet is reduced to improve the productivity, the green sheet itself has poor flexibility and poor sheet shape retainability, and molding cracking and degreasing cracking occur.

The present invention has been made in view of the above-described conventional problems, and an object of the present invention is to provide a green sheet that is excellent in flexibility and sheet moldability and in which a degreasing treatment can be efficiently performed.

### Solution to Problem

The present inventors have intensively studied to achieve the above object. As a result, the present inventors have found that the above problems can be solved by using a binder resin having a specific glass transition temperature as a binder resin, thereby completing the present invention.

The summary of the present invention is as follows:

[1] A green sheet, comprising a raw material powder and a binder resin, in which the raw material powder contains a silicon nitride powder, and a glass transition temperature of the binder resin is less than −20° C.

[2] The green sheet according to [1] above, having a sheet thickness of 200 μm or more.

[3] The green sheet according to [1] or [2] above, in which the binder resin contains at least one selected from the group consisting of a (meth)acrylic resin, a polyvinyl resin, and polyethylene oxide.

[4] The green sheet according to any one of [1] to [3] above, in which the binder resin contains an acrylic resin.

[5] The green sheet according to any one of [1] to [4] above, including substantially no plasticizer.

[6] A method for producing a silicon nitride sintered body, including the step of: firing the green sheet according to any one of [1] to [5] above after degreasing.

[7] A silicon nitride sintered body obtained by firing the green sheet according to any one of [1] to [5] above.

### Advantageous Effects of Invention

According to the present invention, it is possible to be provided a green sheet that is excellent in flexibility and sheet moldability and in which a degreasing treatment can be efficiently performed, a method for producing a silicon nitride sintered body, including the step of: firing the green sheet after degreasing, and a silicon nitride sintered body.

### DESCRIPTION OF EMBODIMENTS

The green sheet of the present invention includes a raw material powder and a binder resin. Each component will be described in detail below.

### [Raw Material Powder]

In the present invention, the raw material powder is not particularly limited as long as it contains a silicon nitride powder. In particular, in the present invention, the raw material powder preferably contains a silicon nitride powder and a sintering aid described later.

By a silicon nitride powder being contained in the raw material powder, a silicon nitride sintered body that has high strength and is excellent in thermal conductivity and insulating properties can be obtained when a green sheet including the raw material powder is fired.

### <Silicon Nitride Powder>

As the silicon nitride powder (Si₃N₄ powder), a commonly available silicon nitride powder can be used, and silicon nitride powders produced by various production methods such as reductive nitriding method, direct nitriding method, and imide decomposition method can be used without particular limitation.

The average particle size D₅₀ of the silicon nitride powder is not particularly limited, and is, for example, 0.5 to 10 μm, and preferably 1 to 3 μm in consideration of, for example, ease of sintering.

In the present specification, the average particle size D₅₀ is a value based on 50% volume measured by a laser diffraction scattering method.

The specific surface area of the silicon nitride powder is not particularly limited, and is preferably 2 to 20 m²/g, and more preferably 5 to 15 m²/g. The specific surface area is measured using a single point BET method based on nitrogen gas adsorption.

As the silicon nitride powder, either a type or B type can be used.

For example, when an a type silicon nitride powder is used, a silicon nitride powder having an α-conversion rate of silicon nitride in the raw material powder of 80% or more can be used. On the other hand, when a B type silicon nitride powder is used, a silicon nitride powder having an β-conversion rate of silicon nitride in the raw material powder of 80% or more can be used.

In the present invention, a silicon nitride powder containing both α type and β type can be used.

The α-conversion rate and the β-conversion rate of the silicon nitride powder mean the peak intensity rate of the α phase and the peak intensity rate of the β phase relative to the total of the α phase and the β phase in the silicon nitride powder, respectively for the α-conversion rate, [100× (peak intensity of α phase)/(peak intensity of α phase+peak intensity of β phase)] and for the β-conversion rate, [100× (peak intensity of β phase)/(peak intensity of α phase+peak intensity of β phase)], and are determined by powder X-ray diffractometry (XRD) using the CuKα line. More specifically, the α-conversion rate and the β-conversion rate can be determined by calculating the mass ratios of the α phase and the β phase of the silicon nitride powder by the method described in C. P. Gazzara and D. R. Messier: Ceram. Bull., 56 (1977), 777-780.

In the present invention, the raw material powder preferably contains 65% by mass or more of the silicon nitride powder, and more preferably contains 75% by mass or more, still more preferably 87% by mass or more, and further preferably 90% by mass or more of the silicon nitride powder. By firing a green sheet in which the amount of silicon nitride in the raw material powder is in the above range, a silicon nitride sintered body having high strength, high thermal conductivity, and high insulating properties can be obtained.

### <Sintering Aid>

The raw material powder preferably further contains a sintering aid. A metal oxide can be used as the sintering aid.

By using the metal oxide as the sintering aid, the silicon nitride powder is more likely to be sintered, and a sintered body that is denser and has higher strength is easily obtained. There is also an advantage that a metal oxide is inexpensive and easy to handle.

Examples of the metal oxide used as the sintering aid include an oxide of at least one rare earth element and/or an oxide of magnesium.

More specifically, examples of the metal oxide include an oxide of rare earth elements such as yttria (Y₂O₃) and ceria (CeO), and magnesia (MgO). Among these, yttria is more preferred. The metal oxide can be used alone or in combination of two or more types.

In addition to the metal oxide, a compound having no oxygen can be used as the sintering aid. By using such a compound having no oxygen as the sintering aid, the amount of oxygen that is derived from the sintering aid and is dissolved in silicon nitride can be reduced. As a result, a silicon nitride sintered body having a high thermal conductivity can be obtained.

As a compound having no oxygen, a carbonitride compound containing a rare earth element or a magnesium element (hereinafter also referred to as a specific carbonitride compound) is preferred. By using such a specific carbonitride compound, a silicon nitride sintered body having a high thermal conductivity as described above is easily obtained.

In a carbonitride compound containing a rare earth element, Y (yttrium), La (lanthanum), Sm (samarium), Ce (cerium) and the like are preferable as the rare earth element.

Examples of the carbonitride compound containing a rare earth element include Y₂Si₄N₆C, Yb₂Si₄N₆C, and Ce₂Si₄N₆C, and among these, Y₂Si₄N₆C and Yb₂Si₄N₆C are preferable from the viewpoint of easily obtaining a silicon nitride sintered body having a high thermal conductivity.

Examples of the carbonitride compound containing a magnesium element include MgSi₄N₆C.

These specific carbonitride compounds can be used alone or in combination of two or more types.

Among the above carbonitride compounds containing a rare earth element or a magnesium element, Y₂Si₄N₆C and MgSi₄N₆C are particularly preferable.

In the present invention, a mixture of the metal oxide and the compound having no oxygen can be also used as a sintering aid. Specific examples of the metal oxide and the compound having no oxygen are as described above.

When a mixture of the metal oxide and the compound having no oxygen is used as a sintering aid, the mass ratio (compound having no oxygen/metal oxide) between the compound having no oxygen, typically the specific carbonitride compound and the metal oxide, which are contained in the sintering aid, is preferably 0.2 to 4, and more preferably 0.6 to 3. When the mass ratio is in such a range, a silicon nitride sintered body that is denser and has a higher thermal conductivity can be easily obtained.

The amount of the sintering aid in the raw material powder contained in the green sheet of the present invention is not particularly limited, and is preferably 3 to 50 parts by mass, more preferably 3 to 30 parts by mass, and further preferably 5 to 15 parts by mass relative to 100 parts by mass of the silicon nitride powder. When the amount of the sintering aid is in the above range, sintering of the green sheet easily proceeds, and a dense sintered body can be obtained.

As described above, when the sintering aid is a mixture of a metal oxide and a compound having no oxygen, the total amount of the mixture is set to be within the above range. The mass ratio between a metal oxide and a compound having no oxygen in the sintering aid is as described above.

### [Binder Resin]

The glass transition temperature of the binder resin contained in the green sheet of the present invention needs to be less than −20° C.

When the glass transition temperature (Tg) of the binder resin is −20° C. or more, the flexibility of the green sheet is decreased, and problems on sheet moldability such as generation of cracks in the sheet itself easily occur.

In particular, as will be described later, in an embodiment of a green sheet including no plasticizer, the above problems become more apparent.

The glass transition temperature of the binder resin is preferably −23° C. or less, more preferably −30° C. or less, and further preferably −35° C. or less. When the glass transition temperature is in the above range, the flexibility of the green sheet is excellent, and the sheet moldability is also excellent.

The lower limit of the glass transition temperature of the binder resin is not particularly limited, and is, for example, 70° C. or more, specifically −66° C. or more.

The glass transition temperature can be measured using, for example, a differential scanning calorimeter (DSC).

The binder resin contained in the green sheet of the present invention is not particularly limited as long as it has the above glass transition temperature. As such a binder resin, at least one selected from the group consisting of a (meth)acrylic resins, a polyvinyl resin, and polyethylene oxide can be used.

The (meth)acrylic resin is not particularly limited as long as it is a resin having a (meth)acrylic skeleton as the main chain and has the above glass transition temperature.

Examples of the (meth)acrylic resin include a (co)polymer of a monomer component containing 1, or 2 or more (meth)acrylic ester monomers.

The (meth)acrylic ester monomer is an ester of acrylic acid and/or methacrylic acid; and an alcohol compound. Examples of the alcohol compound include an alcohol compound having 1 to 30 carbon atoms, for example, an alcohol compound having an alkyl group having 1 to 30 carbon atoms. The alcohol compound can be an aliphatic alcohol or an aromatic alcohol. An example of the alcohol compound is an alcohol compound in which the alkyl group having 1 to 30 carbon atoms can be a linear alkyl group or a branched alkyl group, and a part of the hydrogen atoms of the linear or branched alkyl group can be substituted with an aromatic ring, a hydroxy group, an amino group, a halogen atom, or the like. 1, or 2 or more of such (meth)acrylic ester resin compounds can be used to obtain a (meth)acrylic resin having a glass transition temperature in the above range.

In the present specification, the expression of (meth)acryl indicates that one or both of methacrylic and acrylic are included, and the expression of (meth)acrylic ester indicates that one or both of methacrylic ester and acrylic ester are included.

The glass transition temperature of the binder resin can be adjusted depending on, for example, the type of a polymer constituting the binder resin, the type of a side chain, the length of a side chain, the type of a substituent, the presence or absence of a cross-linked structure, the molecular weight, and the like. For example, by incorporating a unit having a longer side chain into the resin structure, the glass transition temperature of the binder resin can be decreased. For example, a binder resin having a resin structure having a linear alkyl group having 4 to 20 carbon atoms in a side chain can be used.

In the present invention, from the viewpoint of the glass transition temperature, a (meth)acrylic resin is preferably used, and an acrylic resin is more preferably used as the binder resin.

The green sheet of the present invention preferably includes 70% by mass or more, more preferably 80% by mass or more, and further preferably 90% by mass or more of an acrylic resin based on the total amount of the binder resin.

The weight-average molecular weight of the binder resin included in the green sheet of the present invention is not particularly limited as long as the moldability and flexibility in molding the green sheet are good. The range of the weight-average molecular weight of the binder resin is, for example, 30,000 to 3,000,000, preferably 40,000 to 2,000,000, and more preferably 50,000 to 1, 500,000.

The weight-average molecular weight of the binder resin can be determined using gel permeation chromatography (GPC) in terms of polystyrene.

### [Green Sheet]

The green sheet of the present invention includes the above raw material powder and binder resin.

For the amount of the binder resin in the green sheet of the present invention, the percentage can be appropriately determined depending on the molding method, and is preferably 3 to 40 parts by mass, and more preferably 10 to 30 parts by mass relative to 100 parts by mass of the raw material powder.

When the amount of the binder resin is in the above range, a green sheet excellent in flexibility and sheet moldability (sheet shape retainability) is obtained, the filling property of the raw material powder can be improved, and a stable firing shrinkage rate can be obtained. In addition, the binder resin can be efficiently removed in degreasing of the green sheet.

As described above, the green sheet of the present invention preferably includes the raw material powder and the binder resin in the above amount percentage. The percentage of the raw material powder in the entire green sheet of the present invention is preferably 70% by mass or more, and more preferably 80% by mass or more.

In one embodiment of the present invention, the green sheet preferably includes substantially no plasticizer.

Conventionally, in the formation of a green sheet, a slurry containing a raw material powder including a raw material powder and a sintering aid, a binder resin for sheet shape retainability, a plasticizer for imparting flexibility, and an organic substance such as a solvent or a surfactant described later is used. The solvent and the surfactant can be removed by vaporization by heating with hot air or the like after the slurry is molded into a sheet shape during formation of the green sheet.

On the other hand, the binder resin and the plasticizer need to be removed in the degreasing step provided after the drying step. The larger the amount of the organic substance is, the longer the time required for a degreasing treatment is, which decreases productivity. In addition, organic substances tend to remain as impurities, and physical properties of the silicon nitride sintered body may be deteriorated.

As a result of intensive studies, the present inventors have found that by using a binder resin having a specific glass transition temperature as the binder resin, a green sheet excellent in sheet shape retainability and flexibility can be obtained without using a plasticizer. Because the amount of the organic substance used in formation of the green sheet can be reduced, the productivity of the green sheet can be improved, and also, the silicon nitride sintered body obtained by degreasing and firing the obtained green sheet has excellent physical properties.

The “including substantially no” means that the content percentage of the plasticizer in the green sheet is less than 1 ppm by mass based on the total amount of the components contained in the green sheet.

The thickness of the green sheet of the present invention is not particularly limited, and can be set in consideration of the target thickness of the silicon nitride sintered body finally produced. For example, from the viewpoint of handleability and the like, the sheet thickness of the green sheet is preferably 200 μm or more, more preferably 250 μm or more, and further preferably 300 μm or more. Because the green sheet of the present invention is excellent in flexibility, it can have the above thickness.

When the thickness of the green sheet increases, the degreasing time generally needs to be increased. For example, when the thickness increases, the amount of the organic substance contained before degreasing also naturally increases, or it takes time to sufficiently vaporize the organic substance due to the variation in heat transfer in the thickness direction, and thus a long degreasing time is needed.

In this regard, by applying the technique of the present invention and reducing the amount of organic substance removed at the time of degreasing in the green sheet, degreasing can be completed within a relatively short time even in a green sheet having a large thickness, and the production of the sintered body can be efficiently performed. Therefore, it can be said that a green sheet having a thickness in the above range has a large advantage of applying the present invention and is a preferable form.

The upper limit of the thickness of the green sheet is not particularly limited, and the thickness of the green sheet is generally 1.2 mm or less, and in particular 0.8 mm or less.

The size (width and length) of the green sheet is preferably, for example, 100 to 1,000 mm.

In the present invention, specifically, the green sheet can be produced through the following steps. That is, the green sheet is produced through the step (slurry preparation step) of mixing a raw material powder and a binder resin to obtain a slurry molding composition, and the step (molding step) of molding the obtained slurry molding composition into a plate shape or a sheet shape by a doctor blade method or the like. Each step will be described below.

### <Slurry Preparation Step>

In the production of the green sheet of the present invention, the method for preparing the slurry (containing a raw material powder of silicon nitride and the like) to be used is not particularly limited. For example, a slurry can be prepared by measuring out each component constituting the slurry in a predetermined blending amount, and stirring and mixing the components so that the raw material powder of a silicon nitride powder and the like is dispersed in a solvent.

In the slurry preparation step, the amount used of each component constituting the slurry can be appropriately determined so that the green sheet to be obtained has the composition described above. A dispersant or a solvent can be used as needed.

The dispersant is preferably used for increasing the dispersibility of the raw material powder and the like in the molding composition. In general, a surfactant can be suitably used as the dispersant.

Any known surfactant can be used without any limitation. Specific examples of the surfactant that can be suitably used in the present invention include carboxylated trioxyethylene tridecyl ether, diglycerol monooleate, diglycerol monostearate, carboxylated heptaoxyethylene tridecyl ether, tetraglycerol monooleate, hexaglycerol monooleate, sorbitan laurate, sorbitan oleate, sorbitan trioleate, polyoxyethylene sorbitan monolaurate, polyoxyethylene sorbitan monooleate, and polyoxyethylene sorbitan trioleate. These surfactants can be used alone or in combination of two or more types.

The amount of the dispersant can be appropriately selected, and can be usually selected from, for example, the range of 0.1 to 5 parts by mass relative to 100 parts by mass of the raw material powder. In the range, the upper limit value of the amount of the dispersant is preferably 3 parts by mass or less, more preferably 2 parts by mass or less, and further preferably 1 part by mass or less.

The solvent is preferably used to improve the mixing property (ease of slurry preparation) and moldability of the molding composition, and an organic solvent or water is generally suitably used.

Examples of the organic solvent include ketones such as acetone, methyl ethyl ketone, and methyl isobutyl ketone; alcohols such as ethanol, propanol, and butanol; aromatic hydrocarbons such as benzene, toluene, and xylene; and halogenated hydrocarbons such as trichloroethylene, tetrachloroethylene, and bromochloromethane. The organic solvent can be used alone or as a mixture of two or more types. Water can be used without being limited to general tap water, pure water, or the like.

The amount of the solvent can be appropriately selected, and can be usually selected from, for example, the range of 50 to 150 parts by mass relative to 100 parts by mass of the total amount of the raw material powder and the binder resin.

When the viscosity of the molding composition obtained using the solvent is low, a procedure of removing a part of the solvent in the molding composition can be performed to adjust the viscosity to be suitable for the next step. Examples of the procedure include a procedure of stirring the composition under a vacuum atmosphere and distilling off the solvent.

For mixing the components, a known mixing apparatus can be used.

Examples of the mixing apparatus include a known mixing apparatus such as an ultrasonic dispersing apparatus, a ball mill, a bead mill, a roll mill, a homomixer, an ultramixer, a disperse mixer, a penetrating type high-pressure dispersing apparatus, a collision type high-pressure dispersing apparatus, a porous type high-pressure dispersing apparatus, a lump removing type high-pressure dispersing apparatus, a (collision+penetrating) type high-pressure dispersing apparatus, or an ultrahigh-pressure homogenizer.

In order to sufficiently mix the components, the components are preferably generally mixed in multiple batches, for example, two batches. For example, when mixing is performed in two batches, for the first batch, a raw material powder, and a dispersant and a solvent as needed, are added and mixed, and for the second batch, a binder resin, and further a solvent as needed, are added to the mixture of the first batch, and the mixture is mixed to prepare a slurry.

Additionally, after mixing, a procedure such as filtration with a filter can be performed to remove lumps in the slurry as needed.

### <Molding Step>

In the molding step, the method of molding the slurry molding composition into a sheet shape is not particularly limited, and a known method and apparatus can be used. For example, the molding composition can be molded into a sheet shape by a doctor blade method, an extrusion molding method, or the like.

When a solvent is used in the slurry preparation step, a drying step is preferably provided after the molding step.

### <Drying Step>

In the drying step, the method of drying the molded body that is molded into a sheet shape is not particularly limited, and a known method and apparatus can be used. In general, a green sheet can be obtained by drying a molded body at a temperature of the boiling point or more of the solvent in air or nitrogen atmosphere to remove the solvent.

The drying temperature in the drying step is appropriately set depending on the type of the solvent or surfactant used in the molding composition. Though the drying temperature can be set in consideration of the boiling point of the solvent to vaporize the solvent or the like used, when the drying temperature is too high, bumping of the solvent may occur, cracks in a green sheet may be generated, and flatness may be deteriorated (irregularities may be generated). Therefore, for example, a drying temperature of about the boiling point of the solvent used+50° C. is preferably adopted. The drying can be performed, for example, by blowing hot air.

As described above, in the present invention, the amount of the organic substance of the green sheet when the green sheet is subjected to the following degreasing step of a green sheet can be significantly reduced.

Specifically, the amount of the organic substance contained in the green sheet after the drying step is preferably 40 parts by mass or less, more preferably 30 parts by mass or less, and further preferably 25 parts by mass or less relative to 100 parts by mass of the raw material powder.

By controlling the amount of the organic substance contained in the green sheet before the degreasing step within the above range, degreasing can be performed efficiently and sufficiently even in a short time.

### [Method for Producing Silicon Nitride Sintered Body]

According to one embodiment of the present invention, a silicon nitride sintered body can be produced by firing the green sheet of the present invention after degreasing. The method for producing a silicon nitride sintered body of the present invention preferably has the following degreasing step and firing step.

### <Degreasing Step>

The degreasing step is a step for degreasing the binder resin and the remaining organic substance from the green sheet.

The heating in the degreasing step can be performed under an inert gas atmosphere or in air, and is preferably performed in air. In the present specification, the inert gas atmosphere means a nitrogen atmosphere or an argon atmosphere.

The heating temperature in the degreasing step can be appropriately selected depending on the type of the raw material powder and the binder resin and the difference of atmosphere, and is selected from, for example, the range of 450 to 650° C. The heating time is, for example, about 1 to 6,000 minutes. When the heating temperature and the heating time in the above ranges are employed, the organic substance such as a binder can be degreased.

As described above, the green sheet of the present invention has excellent flexibility, thus a plasticizer needs not to be added, and the amount of the organic substance to be degreased in the degreasing step is less. Therefore, the heating time in the degreasing step can be shortened as compared with the conventional one.

For example, the heating time in the degreasing step is preferably 100 to 5,000 minutes, more preferably 1,000 to 4,500 minutes, and further preferably 2,000 to 4,000 minutes. When the heating time is the lower limit value or more, degreasing can be sufficiently performed. In the present invention, when the heating time is the upper limit value or less, the degreasing efficiency can be increased.

In the present invention, a green sheet excellent in flexibility can be obtained without using a plasticizer, thus the organic substance can be efficiently removed in the degreasing step, and as a result, a silicon nitride sintered body can be produced with high production efficiency.

### <Firing Step>

After the degreasing step is performed, a silicon nitride sintered body can be obtained by performing a firing step.

The firing step can be performed under an inert gas atmosphere or in air, and is preferably performed under an inert atmosphere. The firing can be performed at normal pressure or under pressure.

The firing temperature is not particularly limited, and is preferably appropriately set depending on the composition of the raw material powder. From the viewpoint of, for example, ease of the progress of sintering and suppressing decomposition of the raw material powder, in particular, silicon nitride, the firing temperature can be, for example, 1,200 to 1,800° C. The firing time is not particularly limited, and is preferably about 3 to 20 hours.

In the green sheet of the present invention, the raw material powder contains a silicon nitride powder, and thus the firing temperature is preferably 1,700 to 1,800° C.

After the degreasing step and the firing step described above, a silicon nitride sintered body obtained by firing the green sheet, can be obtained.

In the present invention, as described above, the amount of the organic substance contained in the green sheet can be reduced, thus degreasing can be performed efficiently and sufficiently, and as a result, the production efficiency of the production of a silicon nitride sintered body can be dramatically increased.

In addition, a green sheet excellent in sheet shape retainability and flexibility can be obtained even though the amount of the organic substance contained in the green sheet is significantly reduced, and using the green sheet, a silicon nitride sintered body having less impurities resulting from insufficient degreasing and the like can be finally obtained.

Therefore, the obtained silicon nitride sintered body has excellent properties, for example, an excellent thermal conductivity and insulating properties.

The silicon nitride sintered body can be subjected to a blast treatment or the like after firing to remove attached substances such as the raw material powder attached.

The silicon nitride sintered body of the present invention can be used in various industrial materials.

For example, the silicon nitride sintered body can be used in ecologically friendly vehicles such as an electric vehicle, a hydrogen-fueled vehicle, and a hybrid vehicle, and as insulating substrates for power semiconductor devices in the field of renewable energies such as solar power generation and wind power generation.

Further, the silicon nitride sintered body can be also used as a turbine blade for a jet engine that requires high reliability by forming a composite material with silicon carbide fibers.

### EXAMPLES

Hereinafter, Examples are shown to describe the present invention more specifically, but the present invention is not limited to these Examples.

In Examples, the following raw materials were used.

### (Raw Material Powder)

A raw material powder containing a silicon nitride powder and a sintering aid below was used.

### <Silicon Nitride Powder>

Average particle size D₅₀: 1.8 μm
Specific surface area: 7 m²/g
β-conversion rate: 99%

### <Sintering Aid>

1. Compound Having No Oxygen: Y₂Si₄N₆C Powder, MgSi₄N₆C Powder
(i) Y₂Si₄N₆C powder was prepared by heating yttria (manufactured by Shin-Etsu Chemical Co., Ltd.), a silicon nitride powder (silicon nitride powder described above), and a carbon powder (manufactured by Mitsubishi Chemical Corporation) for synthesis using the following reaction formula.

8Si₃N₄+6Y₂O₃+15C+2N₂→6Y₂Si₄N₆C+9CO₂
(ii) MgSi₄N₆C powder was also prepared in the same manner by heating for synthesis using the following reaction formula.

Si₃N₄+MgSiN₂+C→MgSi₄N₆C

### 2. Metal Oxide

Yttria (Y₂O₃) (manufactured by Shin-Etsu Chemical Co., Ltd.)

### (Binder)

Each acrylic resin (manufactured by FUJIKURA KASEI CO., LTD.) having a glass transition temperature Tg shown in Tables 1 and 2 was used as a binder resin.

The glass transition temperature of the binder resin was measured under the following conditions.

Measuring apparatus: DSC-60 (SHIMADZU CORPORATION)

### Measurement Temperature Program

First run: temperature rise from room temperature to 200° C., temperature rise rate of 20° C./min
Hold: 200° C., 5 minutes
Cooling: cooling from 200° C. to −95° C., cooling rate of −20° C./min
Hold: −95° C., 5 minutes
Second run: temperature rise from −95° C. to 100° C., temperature rise rate of 10° C./min

### (Dispersant)

As a dispersant, “Celuna D-735” manufactured by CHUKYO YUSHI CO., LTD. was used.

### <Evaluation Method>

### (1) Evaluation of Green Sheet

### (i) Cracking Evaluation of Green Sheet

The cracking of the green sheet after molding was evaluated as follows.

After the green sheet was molded using the molding composition, the appearance was observed. A green sheet in which the length of the cracked green sheet was less than 3% relative to the molded length was determined as passing (A), and a green sheet in which the length of the cracked green sheet was 3% or more relative to the molded length was determined as failure (X).

### (ii) Evaluation of Flexibility of Green Sheet

For the evaluation of the flexibility of the green sheet after molding, a green sheet in which no crack was generated when the green sheet was bent 90° was determined as passing (A), and a green sheet in which a crack was generated when the green sheet was bent 900 was determined as failure (X).

### (2) Evaluation of Degreasing Cracking of Green Sheet

Each green sheet obtained in Examples and Comparative Examples was degreased, and then degreasing cracking was evaluated. For cracking at the time of degreasing, the appearance of the sheet after degreasing was observed, and a green sheet that had no crack was determined as passing (A), and a green sheet that had an observable crack was determined as failure (X).

(3) Relative Density The density of each silicon nitride sintered body was determined by the Archimedes method using a high-precision hydrometer D-H (trade name: manufactured by TOYO SEIKI CO., LTD.). The relative density was determined by dividing the obtained density value by the theoretical density in which the silicon nitride and the sintering aid were taken into consideration.

### (4) Thermal Conductivity

The thermal diffusivity was measured for each sintered body using a laser flash method thermophysical property measuring apparatus (LFA-502, manufactured by KYOTO ELECTRONICS MANUFACTURING CO., LTD.). The thermal conductivity can be determined by multiplying the thermal diffusivity, the density of the sintered body, and the specific heat of the sintered body. For the specific heat of the silicon nitride sintered body, the value of 0.68 (J/g·K) was used.

Three pieces were randomly collected from 15 pieces of each sintered body, and test pieces for laser flash method thermophysical property measurement were cut out. The thermal conductivity was calculated from the density and the thermal diffusivity of each of three test pieces, and the average value of the thermal conductivities of the three test pieces was used as the thermal conductivity of the sintered body.

### (5) Bending Strength

Ten pieces were randomly collected from 12 pieces excluding the three pieces used for measuring the thermal conductivity, and test pieces for measuring three-point bending strength were cut out. The three-point bending strength of each of 10 test pieces was measured by a method according to ISO 23242: 2020. At this time, a test jig having a distance between fulcrums of 15 mm was used. The average value of the three-point bending strengths of 10 test pieces was shown as the three-point bending strength of the sintered body.

### Example 1

100 parts by mass of a silicon nitride powder, 2 parts by mass of Y₂Si₄N₆C, 3 parts by mass of yttria, 5 parts by mass of MgSi₄N₆C, and 0.5 parts by mass of a dispersant were weighed, and pulverized and mixed in a ball mill for 24 hours using water as a solvent, a resin pot, and silicon nitride balls. Water was weighed in advance so that the concentration of the slurry would be 60% by mass, and was put into the resin pot. After pulverizing and mixing, 22 parts by mass of the binder shown in the table was added, and the mixture was further mixed for 12 hours to obtain a slurry molding composition. Then, the molding composition was defoamed using a vacuum defoaming apparatus (manufactured by Sayama Riken Corporation), and the viscosity was adjusted to produce a slurry for coating. Then, sheet molding was performed by a doctor blade method using the viscosity adjusted slurry for coating, and the sheet was dried at 150° C. in air to vaporize the solvent, thereby a green sheet having a width of 750 mm and a thickness of 420 μm was obtained.

The green sheet obtained as described above was degreased at a temperature of 550° C. in dry air to obtain a degreased green sheet.

Then, the green sheet after degreasing was put in a firing container and fired at 1,780° C. for 9 hours under a nitrogen atmosphere and a pressure of 0.03 MPa-G to obtain a silicon nitride sintered body.

The evaluation of the obtained green sheet and silicon nitride sintered body is shown in Table 1.

### Examples 2 to 6

A green sheet was produced in the same manner as in Example 1 except that the type of the binder resin was changed as shown in Table 1, and then the green sheet was fired to obtain a silicon nitride sintered body. The evaluation of the obtained green sheet and silicon nitride sintered body is shown in Table 1.

### Comparative Examples 1 to 8

A green sheet was produced in the same manner as in Example 1 except that the type of the binder resin was changed as shown in Table 2, and then the green sheet was fired to obtain a silicon nitride sintered body. The evaluation of the obtained green sheet and silicon nitride sintered body is shown in Table 2.

### Comparative Example 9

A molding composition was prepared, a green sheet was produced, then the green sheet was fired to obtain a silicon nitride sintered body in the same manner as in Example 1 except that the type of the binder resin was changed as shown in Table 2, and 15 parts by mass of a plasticizer (compound name: glycerin) relative to 100 parts by mass of a silicon nitride powder was blended. The evaluation of the obtained green sheet and silicon nitride sintered body is shown in Table 2. In Comparative Example 9, as shown in Table 2, the time required for the degreasing step was longer than those in Examples, and the productivity was inferior.

### Comparative Example 10

A molding composition was produced and a green sheet was produced in the same manner as in Comparative Example 9 except that the degreasing time was 65 hours. In observation of the silicon nitride sintered body after firing, discoloration caused by the organic component that could not be removed was observed, and thus degreasing was insufficient.

TABLE 1

| | | | | Examples | | | | | |
|---|---|---|---|---|---|---|---|---|---|
| | | | | 1 | 2 | 3 | 4 | 5 | 6 |
| Molding | Binder | Product | | TEM-01 | TEM-02 | TEM-03 | TEM-04 | TEM-05 | TEM-06 |
| composition | | Name | | | | | | | |
| | | Tg | ° C. | −24 | −35 | −45 | −53 | −60 | −64 |
| | Plasticizer | Product | | — | — | — | — | — | — |
| | | Name | | | | | | | |

| Green sheet | Crack | | A | A | A | A | A | A |
|---|---|---|---|---|---|---|---|---|
| | Flexibility | | A | A | A | A | A | A |
| Degreasing time | | h | 65 | | | | | |
| Degreasing cracking of green sheet | | | A | A | A | A | A | A |
| Sintered | Relative density | % | 99 | 99 | 99 | 99 | 99 | 99 |
| body | Bending strength | MPa | 700 | 650 | 657 | 668 | 690 | 700 |
| | Thermal conductivity | W/m · K | 84 | 90 | 86 | 87 | 88 | 86 |

TABLE 2

| | | | | Comparative Examples | | | | |
|---|---|---|---|---|---|---|---|---|
| | | | | 1 | 2 | 3 | 4 | 5 |
| Molding | Binder | Product | | TEM-08 | TEM-09 | TEM-10 | TEM-11 | TEM-12 |
| composition | | Name | | | | | | |
| | | Tg | ° C. | 26.6 | 18.4 | 15.1 | 13 | 9 |
| | Plasticizer | Product | | — | — | — | — | — |
| | | Name | | | | | | |
| Green sheet | Crack | | | X | X | X | X | X |
| | Flexibility | | | X | X | X | X | X |
| Degreasing time | | | h | 65 | | | | |
| Degreasing cracking of green sheet | | | | A | A | A | A | X |
| Sintered | Relative density | | % | 99 | 99 | 99 | 99 | 99 |
| body | Bending strength | | MPa | — | — | — | — | — |
| | Thermal conductivity | | W/m · K | — | — | — | — | — |
| | | | | Comparative Examples | | | | |
| | | | | 6 | 7 | 8 | 9 | 10 |
| Molding | Binder | Product | | TEM-13 | TEM-14 | TEM-15 | TEM-10 | TEM-10 |
| composition | | Name | | | | | | |
| | | Tg | ° C. | 1.7 | −1.6 | −2 | 15.1 | 15.1 |

| | | | | | |
|---|---|---|---|---|---|
| Plasticizer | Product | — | — | — | Glycerin |

Name

| Green sheet | Crack | | X | X | X | A | A |
|---|---|---|---|---|---|---|---|
| | Flexibility | | X | X | X | A | A |
| Degreasing time | | h | 65 | | | 100 | 65 |
| Degreasing cracking of green sheet | | | X | X | X | A | — |
| Sintered | Relative density | % | 99 | 99 | 99 | 99 | — |
| body | Bending strength | MPa | — | — | — | 655 | — |
| | Thermal conductivity | W/m · K | — | — | — | 88 | — |

1. A green sheet, comprising:
a raw material powder and a binder resin,
wherein the raw material powder contains a silicon nitride powder, and
a glass transition temperature of the binder resin is less than −20° C.

2. The green sheet according to claim 1, having a sheet thickness of 200 m or more.

3. The green sheet according to claim 1, wherein the binder resin contains at least one selected from the group consisting of a (meth)acrylic resin, a polyvinyl resin, and polyethylene oxide.

4. The green sheet according to claim 1, wherein the binder resin contains an acrylic resin.

5. The green sheet according to claim 1, comprising substantially no plasticizer.

6. A method for producing a silicon nitride sintered body, comprising the step of: firing the green sheet according to claim 1 after degreasing.

7. A silicon nitride sintered body obtained by firing the green sheet according to claim 1.
